(19) United States
(12) Patent Application Publication
(10) Pub. No.: US 2026/0242184 A1
(43) Pub. Date: Aug. 20, 2026

(54) OVERHEAD CONVEYANCE VEHICLE

(71) Applicant: Murata Machinery, Ltd., Kyoto-shi, Kyoto (JP)

(72) Inventors: Makoto KOBAYASHI, Kyoto-shi (JP); Masayasu KAWABATA, Kyoto-shi (JP)

(21) Appl. No.: 19/159,682

(22) PCT Filed: Jan. 23, 2024
(86) PCT No.: PCT/JP2024/001921

§ 371 Date: Aug. 26, 2025

(30) Foreign Application Priority Data
Jun. 6, 2023 (JP) 2023-093361

(51) Int. Cl. B66C 13/46; B66C 19/00; G01S 17/42; H10P 72/30

(52) U.S. Cl. CPC B66C 13/46; B66C 19/00; G01S 17/42; H10P 72/3221

(57) ABSTRACT

An overhead conveyance vehicle includes a holder to be lifted and lowered with respect to a body and hold an article, a lifting driver to lift and lower the holder, and a processor configured or programmed to recognize a position in a horizontal direction and a position in a height direction of the holder.

### BACKGROUND OF THE INVENTION

### 1. Field of the Invention

The present disclosure relates to overhead conveyance vehicles.

### 2. Description of the Related Art

As a technique related to overhead conveyance vehicles, WO 2020/121765 describes a conveyance vehicle including a lifting platform (holder) provided to be able to be lifted and lowered with respect to a body and including a gripper, and a lifting driver lifting and lowering the lifting platform. In the conveyance vehicle described in WO 2020/121765, a swing detection sensor is provided in the lifting driver. The swing detection sensor sends laser light toward a reflector on an upper surface of the lifting platform, and detects a swing of the lifting platform according to whether reflected light (returning light) has been detected or not.

### SUMMARY OF THE INVENTION

In overhead conveyance vehicles, there is a case that an obstacle is present, for example, at a certain height when a holder is lifted and lowered, and thus, it is desirable that an amount of swing of the holder can be accurately identified along with the height at which the holder is located. In this regard, in the above overhead conveyance vehicle, it is only detected whether an amount of swing of the holder falls within a predetermined range (returning light detected) or is equal to or more than the predetermined range (returning light not detected), and hence, there is a possibility that the amount of swing of the holder cannot be accurately identified nor can the height at which the holder is located be identified.

Thus, example embodiments of the present invention provide overhead conveyance vehicles each capable of accurately identifying an amount of swing of a holder along with a height at which the holder is located.

An overhead conveyance vehicle according to an example embodiment of the present disclosure includes a holder to be lifted and lowered with respect to a body and hold an article, a lifting driver to lift and lower the holder, and a controller configured or programmed to include a processor configured or programmed to recognize a position in a horizontal direction and a position in a height direction of the holder, and a determiner configured or programmed to determine whether or not the position of the holder in the horizontal direction recognized by the processor falls within an acceptable range according to the position of the holder in the height direction recognized by the processor.

In this overhead conveyance vehicle, when the holder is lifted and lowered, it is possible to quantify a swing of the holder while identifying the position of the holder in the height direction from a recognition result of the processor. That is, it is possible to accurately identify the amount of swing of the holder along with the height at which the holder is located.

In the overhead conveyance vehicle according to the above example embodiment, the holder is provided with a reflector, and the processor may be configured or programmed to include a sensor to emit light toward the reflector at a plurality of irradiation angles within a monitoring range including the reflector while detecting a plurality of returning light beams reflected by the reflector in response to the irradiation at the plurality of irradiation angles, wherein the processor is configured or programmed to obtain the position in the horizontal direction and the position in the height direction of the holder based on detection results of the plurality of detected returning light beams detected by the sensor. In this case, the position in the horizontal direction and the position in the height direction of the holder can be easily detected using the returning light.

In the overhead conveyance vehicles according to the above example embodiments, when a traveling direction of the overhead conveyance vehicle is defined as an X direction, and a horizontal direction orthogonal to the X direction is defined as a Y direction, the sensor may be configured or programmed to emit light toward the reflector within the monitoring range so as to scan in the Y direction, and the processor may be configured or programmed to obtain an angle average and a distance average for optical axes of the plurality of detected returning light beams, and obtain a position of the holder in the Y direction based on the angle average and the distance average. In this case, it is possible to accurately identify the amount of swing of the holder in the Y direction.

In the overhead conveyance vehicles according to the above example embodiments, a shape of the reflector may include a shape in which a width in the Y direction varies with increasing distance in the X direction, and the processor may be configured or programmed to obtain a position of the holder in the X direction based on a number of returning light beams stored in advance and a number of the plurality of detected returning light beams. In this case, it is possible to accurately identify an amount of swing of the holder in the X direction along with the height.

The overhead conveyance vehicles according to any one of the above example embodiments, may further include a determiner configured or programmed to determine whether or not the position of the holder in the horizontal direction recognized by the processor falls within an acceptable range. In this case, it is possible to determine whether or not the amount of swing of the holder can be accepted.

The overhead conveyance vehicles according to any one of the above example embodiments, may further include a lateral transfer mechanism moving the lifting driver laterally with respect to the body. This makes it possible to accurately identify the amount of swing of the holder along with the height at which the holder is located, for example, during lifting and lowering when the article is transferred to and from a placement section located laterally to the body.

In the overhead conveyance vehicles according to the above example embodiments, when the lifting driver is laterally moved by the lateral transfer mechanism, the processor may be configured or programmed to correct the position of the holder in the horizontal direction based on a correction value for a tilt of the lifting driver, the correction value being stored in advance. This makes it possible to accurately identify the amount of swing of the holder along with the height, even when a direction of irradiation from the sensor is inclined due to the tilt of the lifting driver at the time of laterally moving the lifting driver by the lateral transfer mechanism.

The overhead conveyance vehicles according to any one of the above example embodiments, may further include a storage to store, for a predetermined period in time series, the position in the horizontal direction and the position in the height direction of the holder that are recognized by the processor. In this case, a behavior of the holder can be identified, and the identified behavior of the holder can be utilized for, for example, maintenance.

According to example embodiments of the present disclosure, it is possible to accurately identify the amount of swing of the holder along with the height at which the holder is located.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a side view illustrating an overhead conveyance vehicle according to an example embodiment of the present invention.

FIG. 2 is a front view illustrating a sensor and a reflector in an initial state.

FIG. 3A is a schematic plan view illustrating the reflector in FIG. 2. FIG. 3B is a schematic perspective view illustrating the sensor and the reflector in FIG. 2.

FIG. 4 is a block diagram illustrating a conveyance vehicle controller.

FIG. 5 is a front view illustrating the sensor and the reflector during transfer.

FIG. 6A is a schematic plan view illustrating the reflector in FIG. 5. FIG. 6B is a schematic perspective view illustrating the sensor and the reflector in FIG. 5.

### DETAILED DESCRIPTION OF EXAMPLE EMBODIMENTS

Hereinafter, example embodiments will be described in detail with reference to the drawings. In the description of the drawings, the same or corresponding elements are denoted by the same reference numerals, and redundant description is omitted.

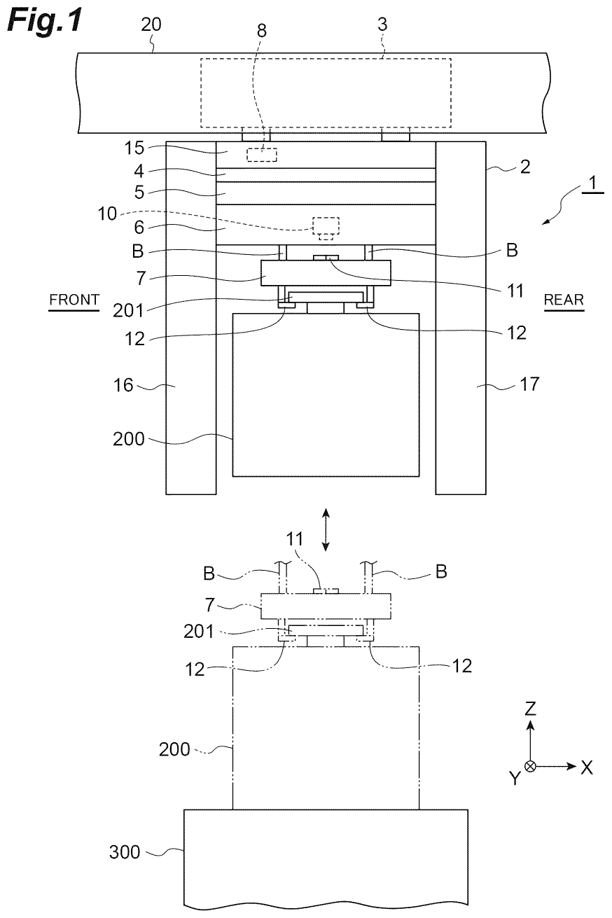

As illustrated in FIG. 1, an overhead conveyance vehicle 1 according to an example embodiment travels along a track 20 installed near a ceiling of a clean room in which semiconductor devices are manufactured. The track 20 provides a travel path of the overhead conveyance vehicle 1. The overhead conveyance vehicle 1 is a conveyance vehicle capable of conveying an article 200 and transferring the article 200 to a load port 300. The article 200 is, for example, a FOUP (front opening unified pod) in which a plurality of semiconductor wafers are housed. The load port 300 is, for example, a placement section provided in a processing device that performs various types of processing on semiconductor wafers. The article 200 and the load port 300 are not particularly limited. In this example, the load port 300 is located away from the track 20 in a lateral direction (sideways in a traveling direction of the overhead conveyance vehicle 1).

In the following description, the terms “upper” and “lower” respectively correspond to an upper direction and a lower direction in a vertical direction. The term “front” corresponds to a front side of the overhead conveyance vehicle 1 in the traveling direction, and the term “rear” corresponds to a rear side of the overhead conveyance vehicle 1 in the traveling direction. An X direction corresponds to the traveling direction, a Z direction corresponds to the up-down direction, and a Y direction corresponds to a lateral direction (horizontal direction orthogonal to the traveling direction).

The overhead conveyance vehicle 1 includes a frame unit 2, a traveling unit 3, a lateral unit 4, a theta unit 5, a lifting driver 6, a holder 7, and a conveyance vehicle controller 8. The frame unit 2 includes a center frame 15, a front frame 16, and a rear frame 17. The frame unit 2 defines a body. The front frame 16 extends toward the lower side from an end portion on a front side of the center frame 15. The rear frame 17 extends toward the lower side from an end portion on a rear side of the center frame 15.

The traveling unit 3 is disposed on an upper side of the center frame 15. The traveling unit 3 travels along the track 20 by, for example, receiving electric power supplied from a high-frequency current line installed along the track 20 in a non-contact manner. The lateral unit 4 is disposed on a lower side of the center frame 15. The lateral unit 4 moves the theta unit 5, the lifting driver 6, and the holder 7 in the Y direction (lateral direction) with respect to the frame unit 2. The lateral unit 4 slides the theta unit 5, the lifting driver 6, and the holder 7 along the Y direction with respect to the frame unit 2 by, for example, a driving force (for example, a drive motor, a pulley, a belt, etc.) of a drive mechanism (not illustrated). The lateral unit 4 defines a lateral transfer mechanism. The theta unit 5 is disposed on a lower side of the lateral unit 4. The theta unit 5 rotates the lifting driver 6 and the holder 7 in a horizontal plane.

The lifting driver 6 is disposed on a lower side of the theta unit 5. The lifting driver 6 lifts and lowers the holder 7 in the Z direction by unwinding and winding suspending members B, such as a plurality of belts, connected to the holder 7. The suspending members B have flexibility. The lifting driver 6 defines a lifting driver. The holder 7 is disposed on a lower side of the lifting driver 6. The holder 7 is provided to be able to be lifted and lowered with respect to the frame unit 2 by the lifting driver 6. The holder 7 includes a pair of holding sections 12, such as grippers, that are openable and closeable along the horizontal direction. The holder 7 holds a flange 201 of the article 200 with the pair of holding sections 12.

The conveyance vehicle controller 8 is disposed in the center frame 15. The conveyance vehicle controller 8 may be an electronic control unit including a CPU (central processing unit), a ROM (read only memory), a RAM (random access memory), and the like. The conveyance vehicle controller 8 is configured or programmed to control individual sections of the overhead conveyance vehicle 1. The conveyance vehicle controller 8 may include a plurality of electronic control units. When the conveyance vehicle controller 8 includes the plurality of electronic control units, these units may logically construct a single unit by being connected via a communication network, such as the Internet or an intranet. The conveyance vehicle controller 8 may be disposed in the front frame 16 or the like.

The overhead conveyance vehicle 1 configured as described above operates, for example, as follows during lateral transfer in which the article 200 is transferred from the load port 300. The overhead conveyance vehicle 1 moves the holder 7 in an advancing direction with respect to the frame unit 2 by driving the lateral unit 4 at a stop position corresponding to the load port 300. In conjunction therewith, the orientation of the holder 7 is adjusted by driving the theta unit 5 as necessary. The advancing direction is a direction in which the holder 7 advances so as to protrude from the frame unit 2 in the lateral direction. Subsequently, the overhead conveyance vehicle 1 causes the holder 7 to be lowered by driving the lifting driver 6, and the holder 7 to hold the flange 201 of the article 200 on the load port 300. The overhead conveyance vehicle 1 causes the holder 7 to be lifted to a lifted end by driving the lifting driver 6. Then, the overhead conveyance vehicle 1 causes the holder 7 to be moved by driving the lateral unit 4 in a retreating direction that is the opposite direction of the advancing direction, and the holder 7 to be located between the front frame 16 and the rear frame 17.

On the other hand, the overhead conveyance vehicle 1 operates, for example, as follows during lateral transfer in which the article 200 is transferred to the load port 300. The overhead conveyance vehicle 1 causes, at the stop position corresponding to the lateral position of the load port, the holder 7 holding the article 200 to be moved in the advancing direction with respect to the frame unit 2 by driving the lateral unit 4. In conjunction therewith, the orientation of the holder 7 is adjusted by driving the theta unit 5 as necessary. Subsequently, the overhead conveyance vehicle 1 causes the holder 7 to be lowered by driving the lifting driver 6 to place the article 200 on the load port 300, and the holder 7 releases the holding of the flange 201 of the article 200. The overhead conveyance vehicle 1 causes the holder 7 to be lifted to the lifted end by driving the lifting driver 6. Then, the overhead conveyance vehicle 1 causes the holder 7 to be moved in the retreating direction by driving the lateral unit 4, and the holder 7 to be located between the front frame 16 and the rear frame 17.

As illustrated in FIGS. 1, 2, 3A, and 3B, the overhead conveyance vehicle 1 includes a sensor 10 and a reflector 11. The sensor 10 may be provided in the lifting driver 6. The sensor 10 is not particularly limited, and is, for example, a laser range finder. The sensor 10 emits laser light beams (light) L toward the reflector 11 at a plurality of irradiation angles within a monitoring range Z including the reflector 11, while detecting a plurality of returning light beams RL reflected by the reflector 11 in response to the emission of the laser light beams. The sensor 10 emits the laser light L toward the reflector 11 in the monitoring range Z so as to scan in the Y direction. The monitoring range Z is an isosceles triangular region with the sensor 10 being a vertex when viewed in the X direction. The sensor 10 is connected to the conveyance vehicle controller 8. The returning light is also referred to as reflected light.

The reflector 11 may be provided on the holder 7. As an example, the reflector 11 is provided in the center of the top portion of the holder 7. The reflector 11 is able to reflect the laser light L of the sensor 10. The reflector 11 is disposed with its reflecting surface facing upward, and is able to reflect the laser light L from above toward the upper direction. The reflector 11 is disposed immediately below the sensor 10 when the lifting driver 6 is in a horizontal state. The reflector 11 is not particularly limited, and various reflectors can be used.

The reflector 11 has a shape in which widths in the Y direction vary with increasing distance from a central portion outward in the X direction. For example, the reflector 11 is a rectangular or substantially rectangular plate structure, and is disposed such that a diagonal line extends in the Y direction in plan view. The reflector 11 has a line-symmetric shape with reference to an axis that passes through the central portion and extends in the X direction. A portion of the reflector 11 may have a shape with its widths in the Y direction being constant. The reflector 11 may include a reflective tape, or may include various structures capable of reflecting the laser light L.

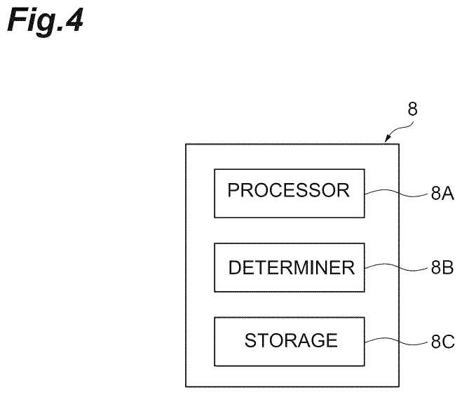

As illustrated in FIG. 4, the t conveyance vehicle controller 8 is configured or programmed to include, as functional components, a processor 8A, a determiner 8B, and a storage 8C. The processor 8A is configured or programmed to obtain (recognize) a position in the horizontal direction and a position in the height direction of the holder 7 based on detection results of the plurality of detected returning light beams RL detected by the sensor 10.

The processor 8A is configured or programmed to obtain an angle average and a distance average for the optical axes of the plurality of detected returning light beams RL, and obtains a position of the holder 7 in the Y direction based on the angle average and the distance average. The processor 8A is configured or programmed to obtain a position of the holder 7 in the X direction based on the number of returning light beams RL stored in advance and the number of the plurality of detected returning light beams RL. The processor 8A is configured or programmed to correct the position of the holder 7 in the horizontal direction based on a correction value for a tilt of the lifting driver 6 during lateral transfer in which the lifting driver 6 is laterally moved by the lateral unit 4, the correction value being stored in advance. Details of each piece of processing of the processor 8A will be described later.

The determiner 8B is configured or programmed to determine whether or not the position of the holder 7 in the horizontal direction recognized by the processor 8A falls within an acceptable range. The determiner 8B may determine whether or not at least any one of the position in the X direction and the position in the Y direction of the holder 7 that are recognized by the processor 8A falls within the acceptable range. The acceptable range may be a given width determined in advance. The acceptable range may be defined by an angle, a width, or the like according to the position of the holder 7 in the height direction. The acceptable range may be a range in the X direction, a range in the Y direction, or a range including both of them.

When determining that the position of the holder 7 in the horizontal direction recognized by the processor 8A does not fall within the acceptable range, the determiner 8B may determine that a swing of the holder 7 equal to or more than the acceptable range has occurred, and may cause an alarm unit (not illustrated) to issue an alarm about a swing detection error. The determination result from the determiner 8B may be transmitted to an external host controller. The storage 8C stores, for a predetermined period in time series, positions in the horizontal direction and positions in the height direction of the holder 7 recognized by the processor 8A. The predetermined period is not particularly limited, and may be a given period determined in advance or a period changeable by a user.

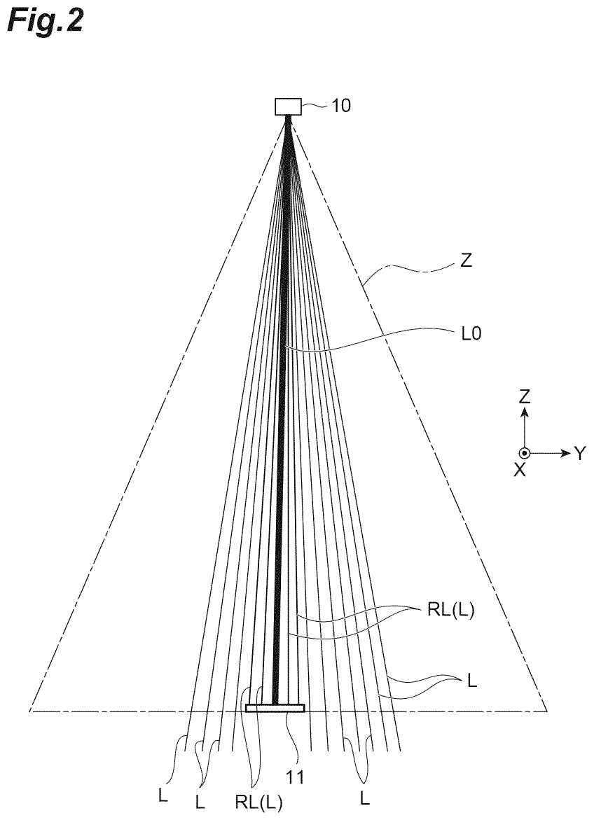

Next, description will be given of a pre-process (preprocessing) before the position in the horizontal direction and the position in the height direction of the holder 7 are obtained. As illustrated in FIG. 2, in an initial state in which the lateral unit 4 does not tilt, the lifting driver 6 does not swing, and the reflector 11 is present immediately below the sensor 10, the sensor 10 emits laser light beams L toward the reflector 11 so as to scan in the Y direction, while detecting a plurality of returning light beams RL reflected by the reflector 11 in response to the emission of the laser light beams.

The processor 8A is configured or programmed to obtain, as an initial angle average α0, an angle average for the optical axes of the plurality of detected returning light beams RL. The angle average may be, for example, an average of an angle of the optical axis of a first returning light RL1 detected first among the plurality of detected returning light beams RL, and an angle of the optical axis of a first returning light RL2 detected last among the plurality of detected returning light beams RL. The first returning light RL1 corresponds to returning light RL relevant to the detection when the state of not detecting returning light RL is switched to the state of having detected it. The second returning light RL2 corresponds to returning light RL relevant to the detection when the state of having detected returning light RL is switched to the state of not detecting it. The initial angle average α0 corresponds to the angle of the optical axis of laser light L0 emitted to the central portion of the reflector 11 in the direction of scanning for optical axes in the initial state.

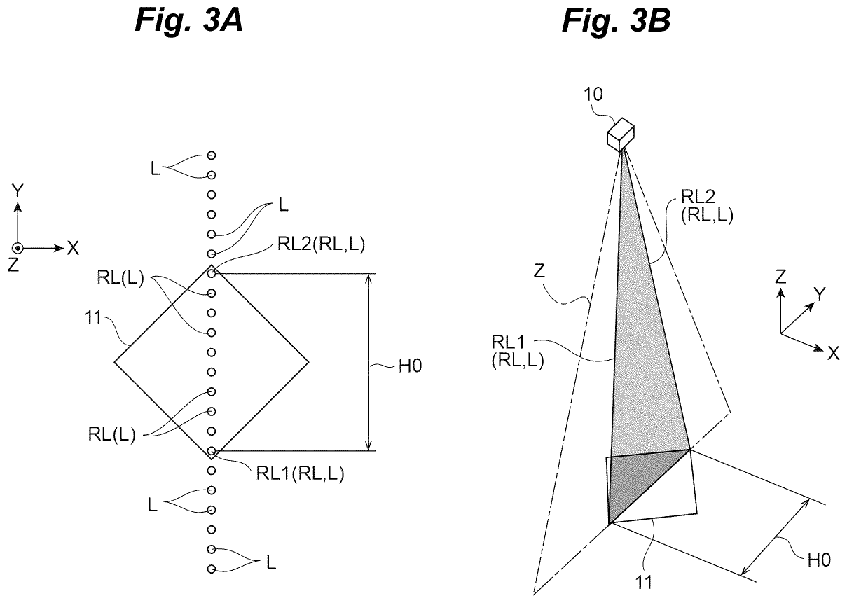

As illustrated in FIGS. 3A and 3B, the processor 8A is configured or programmed to obtain the number of detected returning light beams RL as the number of initial returning light beams. The number of initial returning light beams corresponds to a detection range H0 that is a range, of the reflector 11 (to which laser light beams L are directed), in which returning light beams RL are detected in the initial state. The number of detected returning light beams RL corresponds to the number of optical axes of the detected returning light beams RL. The processor 8A is configured or programmed to store the obtained initial angle average α0 and number of initial returning light beams in the storage 8C.

Note that the above pre-process may be omitted as long as the initial angle average α0 and the number of initial returning light beams are acquired in advance using some method, such as simulation, and stored in the storage 8C. The reference of the angle is not particularly limited, and the angle immediately below the sensor 10 (downward in the vertical direction) may be set to 0°, for example. The references of the positions of the holder 7 in the X direction and the Y direction are not particularly limited, and the position of the holder 7 (sensor 10) in the initial state may be 0. The reference of the position of the holder 7 in the height direction (Z direction) is not particularly limited, and the position of the sensor 10 in the height direction may be 0.

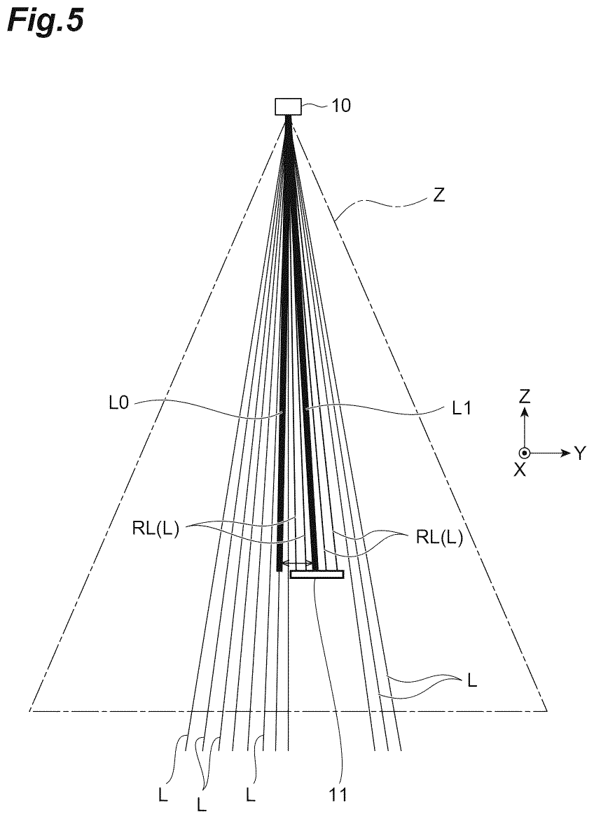

Next, for example, a case will be described that the position in the horizontal direction and the position in the height direction of the holder 7 are obtained during the lateral transfer in which the article 200 is transferred to and from the load port 300 located laterally to the track 20 in plan view. In this example, as illustrated in FIG. 5, the holder 7 swings in the Y direction, and the reflector 11 is present while being shifted from immediately below the sensor 10 in the Y direction.

First, the sensor 10 emits laser light beams L toward the reflector 11 so as to scan in the Y direction, while detecting a plurality of returning light beams RL reflected by the reflector 11 in response to the emission of the laser light beams. The processor 8A obtains an angle average and a distance average for the optical axes of the plurality of detected returning light beams RL as an angle average α1 during transfer and a distance average B1 during transfer. The distance average may be, for example, an average of distances of the optical axes of the plurality of returning light beams RL. The distance of the returning light RL can be acquired, for example, based on the intensity of the returning light RL. The angle average α1 during transfer corresponds to the angle of the optical axis of the laser light L1 emitted to the central portion of the reflector 11 in the direction of scanning for optical axes during transfer.

The processor 8A calculates a difference β between the initial angle average α0 and the angle average α1 during transfer, and obtains a position of the holder 7 in the Y direction according to the following equation (1) regarding the difference β and the distance average B1 during transfer. The position of the holder 7 in the Y direction corresponds to an amount of swing of the holder 7 in the Y direction.

$$Position of holder 7 in Y direction = B 1 \cdot sin β \qquad ( 1 )$$

At this time, the processor 8A is configured or programmed to correct the position of the holder 7 in the horizontal direction based on the correction value stored in advance in the storage 8C. The correction value is a value according to the tilt (posture) of the lifting driver 6. The correction value is a value for correcting the initial angle average α0 according to the tilt of the lifting driver 6. For example, since the lifting driver 6 tilts due to driving or no driving of the lateral unit 4, the amount of driving by the lateral unit 4, the type of the load port 300 to be transferred, the inclination of the track 20, and the like, correction values associated with at least any or some of these are set as a correction value table. As an example, the processor 8A is configured or programmed to acquire a correction value for the tilt of the lifting driver 6 from the correction value table based on the amount of driving by the lateral unit 4, and, when the position of the holder 7 in the Y direction is obtained by the above formula (1), adds or subtracts the correction value to or from the initial angle average α0.

In addition, the position of the holder 7 in the height direction is obtained by the processor 8A based on the distance average B1 during transfer and the difference β, for example, according to the following equation (2).

$$Position of holder 7 in height direction = B 1 \cdot cos β \qquad ( 2 )$$

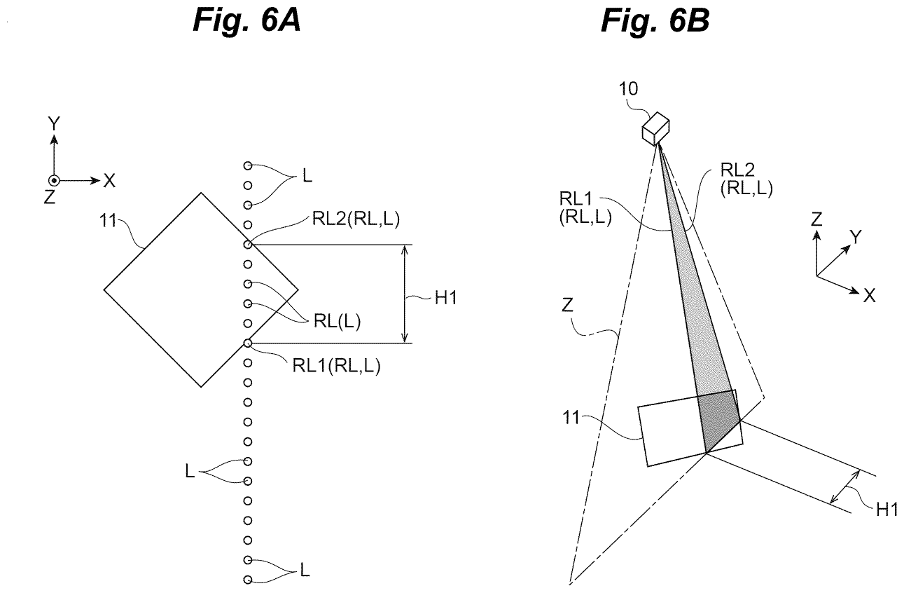

As illustrated in FIGS. 6A and 6B, the processor 8A is configured or programmed to obtain the number of detected returning light beams RL as the number of returning light beams during transfer. The number of returning light beams during transfer corresponds to a detection range H1 that is a range of the reflector 11 in which returning light beams RL are detected during transfer. It is determined that when the scanning position of the laser light L is shifted from the initial state in the X direction, the number of returning light beams during transfer differs from (decreases, in this case) the number of initial returning light beams according to the shape of the reflector 11 (see FIGS. 3A and 6A). Thus, the processor 8A is configured or programmed to obtain, from the difference between the number of initial returning light beams and the number of returning light beams during transfer, a position of the holder 7 in the X direction, for example, according to the following formula (3) using, for example, a conversion factor Gx. The conversion factor Gx is a factor for converting the shift in the X direction from the difference between the number of initial returning light beams and the number of returning light beams during transfer, and may be stored in advance in the storage 8C. The position of the holder 7 in the X direction corresponds to the amount of swing of the holder 7 in the X direction.

$$Position of holder 7 in X direction = ( Number of initial returning light beams - Number of returning light beams during transfer ) \cdot Gx \qquad ( 3 )$$

As described above, in the overhead conveyance vehicle 1, when the holder 7 is lifted and lowered, it is possible to quantify the swing of the holder 7 from the positions of the holder 7 in the X direction and the Y direction while identifying the position of the holder 7 in the height direction. That is, it is possible to accurately identify the amount of swing of the holder 7 along with the height at which the holder 7 is located. The amount of swing of the holder 7 can be controlled by numerical values.

In the overhead conveyance vehicle 1, the holder 7 is provided with the reflector 11, and the sensor 10 emits laser light beams L toward the reflector 11 at a plurality of irradiation angles, while detecting a plurality of returning light beams RL reflected by the reflector 11 in response to the emission of the laser light beams. Then, the processor 8A is configured or programmed to obtain the position in the horizontal direction and the position in the height direction of the holder 7 based on detection results of the sensor 10. In this case, the position in the horizontal direction and the position in the height direction of the holder 7 can be easily detected using the returning light RL.

In the overhead conveyance vehicle 1, the sensor 10 emits laser light L toward the reflector 11 in the monitoring range Z so as to scan in the Y direction. The processor 8A is configured or programmed to obtain the angle average and the distance average for the optical axes of the plurality of detected returning light beams RL, and obtain the position of the holder 7 in the Y direction based on the angle average and the distance average. In this case, it is possible to accurately identify the amount of swing of the holder 7 in the Y direction along with the height.

In the overhead conveyance vehicle 1, the shape of the reflector 11 includes a shape in which widths in the Y direction vary with increasing distance in the X direction. The processor 8A is configured or programmed to obtain the position of the holder 7 in the X direction based on the number of initial returning light beams and the number of returning light beams during transfer that are stored in advance. In this case, it is possible to accurately identify the amount of swing of the holder 7 in the X direction.

The overhead conveyance vehicle 1 further includes the determiner 8B that determines whether or not the recognized position of the holder 7 in the horizontal direction falls within the acceptable range. In this case, it is possible to determine whether or not the amount of swing of the holder 7 can be accepted.

The overhead conveyance vehicle 1 includes the lateral unit 4 that moves the lifting driver 6 laterally with respect to the frame unit 2. This makes it possible to accurately identify the amount of swing of the holder 7 along with the height at which the holder 7 is located, for example, during the lateral transfer.

In the overhead conveyance vehicle 1, when the lifting driver 6 is laterally moved by the lateral unit 4, the processor 8A is configured or programmed to correct the position of the holder 7 in the horizontal direction based on the correction value stored in advance. This makes it possible to accurately identify the amount of swing of the holder 7 along with the height even when the direction of irradiation from the sensor 10 is inclined due to the tilt of the lifting driver 6 at the time of laterally moving the lifting driver 6 by the lateral unit 4. Further, in the overhead conveyance vehicle 1, the position of the holder 7 in the horizontal direction may be corrected based on the correction value for the tilt of the lifting driver 6 following the inclination of the track 20. In this case, even when the lifting driver 6 tilts and the direction of irradiation from the sensor 10 is inclined due to the inclination of the track 20, it is possible to accurately identify the amount of swing of the holder 7 along with the height.

The overhead conveyance vehicle 1 includes the storage 8C that stores, for a predetermined period in time series, the recognized positions in the horizontal direction and positions in the height direction of the holder 7. In this case, behavior of the holder 7 can be identified, and the identified behavior of the holder 7 can be utilized for, for example, maintenance.

In the overhead conveyance vehicle 1, further, the following effects are exhibited. That is, the behavior (the position in the horizontal direction according to the position in the height direction) of the holder 7 can be accurately identified. The absolute position (three-dimensional position) of the holder 7 can be accurately identified. Appropriate control according to the behavior of the holder 7 can be performed. For example, if swing equal to or more than the acceptable range occurs to stop the transfer of the article 200, it is possible to perform control for automatic recovery etc. when the swing diminishes. The size of the reflector 11 does not correlate with an acceptable amount of swing. The size of the reflector 11 can be increased. The amount of swing of the reflector 11 can be calculated in real time by calculation. The angular resolution of the sensor 10 is preferably made finer. Use of the calculation taking into account the tilt of the lifting driver 6 due to a tilt during the lateral transfer, the inclination of the track 20, and the like, makes the lifting driver 6 less likely to be affected by the tilt and inclination.

While the example embodiments have been described above, the present invention is not limited to the above example embodiments. Various modifications can be made without departing from the spirit of the present invention.

In the above example embodiments, the shape of the reflector 11 is not particularly limited. It is only necessary that the shape of the reflector 11 include a shape in which widths in the Y direction vary with increasing distance in the X direction. The shape of the reflector 11 may include a polygonal shape, an elliptical shape, an oval shape, and a shape obtained by combining these shapes, as long as widths in the Y direction vary with increasing distance in the X direction, for example.

In the above example embodiments, a recognition device (processor) includes the sensor 10, but may include an imaging apparatus, such as a stereo camera, in place of the sensor 10. In the above example embodiments, the conveyance vehicle controller 8 is configured or programmed to include the processor 8A, the determiner 8B, and the storage 8C. However, one, some, or all of the processor 8A, the determiner 8B, and the storage 8C may be mounted on an external computer communicable with the overhead conveyance vehicle 1.

Various materials and shapes can be applied to components in the above example embodiments and modifications without being limited to the above-described materials and shapes. The components in the above example embodiments or modifications can be freely applied to components in other example embodiments or modifications. Some of the components in the above example embodiments or modifications can be appropriately omitted without departing from the gist of the present invention. In the above description, the sensor 10 and the processor 8A define a recognition device to recognize the position in the horizontal direction and the position in the height direction of the holder 7.

While example embodiments of the present invention have been described above, it is to be understood that variations and modifications will be apparent to those skilled in the art without departing from the scope and spirit of the present invention. The scope of the present invention, therefore, is to be determined solely by the following claims.

1.-8. (canceled)

9. An overhead conveyance vehicle comprising:
a holder to be lifted and lowered with respect to a body and to hold an article;
a lifting driver to lift and lower the holder; and
a controller configured or programmed to include:
a processor configured or programmed to recognize a position in a horizontal direction and a position in a height direction of the holder; and
a determiner configured or programmed to determine whether or not the position of the holder in the horizontal direction recognized by the processor falls within an acceptable range according to the position of the holder in the height direction recognized by the processor.

10. The overhead conveyance vehicle according to claim 9, wherein
the holder includes a reflector; and
the processor is configured or programmed to include:
a sensor provided in the lifting driver to emit light toward the reflector at a plurality of irradiation angles within a monitoring range including the reflector while detecting a plurality of returning light beams reflected by the reflector in response to the irradiation at the plurality of irradiation angles; wherein
the processor is configured or programmed to obtain the position in the horizontal direction and the position in the height direction of the holder based on detection results of the plurality of returning light beams detected by the sensor.

11. The overhead conveyance vehicle according to claim 10, wherein
when a traveling direction of the overhead conveyance vehicle is defined as an X direction, and a horizontal direction orthogonal to the X direction is defined as a Y direction;
the sensor is configured or programmed to emit light toward the reflector within the monitoring range so as to scan in the Y direction; and
the processor is configured or programmed to obtain an angle average and a distance average for optical axes of the plurality of detected returning light beams, and obtain a position of the holder in the Y direction based on the angle average and the distance average.

12. The overhead conveyance vehicle according to claim 11, wherein
a shape of the reflector includes a shape in which a width in the Y direction varies with increasing distance in the X direction; and
the processor is configured or programmed to obtain a position of the holder in the X direction based on a number of returning light beams stored in advance and a number of the plurality of detected returning light beams.

13. The overhead conveyance vehicle according to claim 9, further comprising a lateral transfer mechanism to move the lifting driver laterally with respect to the body.

14. The overhead conveyance vehicle according to claim 13, wherein when the lifting driver is laterally moved by the lateral transfer mechanism, the processor is configured or programmed to correct the position of the holder in the horizontal direction based on a correction value for a tilt of the lifting driver, the correction value being stored in advance.

15. The overhead conveyance vehicle according to claim 9, further comprising a storage to store, for a predetermined period in time series, the position in the horizontal direction and the position in the height direction of the holder that are recognized by the processor.
